(19) United States
(12) Patent Application Publication
(10) Pub. No.: US 2026/0076130 A1
(43) Pub. Date: Mar. 12, 2026

(54) SUBSTRATE PROCESSING SYSTEM

(71) Applicant: SCREEN Holdings Co., Ltd., Kyoto (JP)

(72) Inventors: Tetsuo ITO, Kyoto (JP); Takaaki SEIWA, Kyoto (JP); Tomohiro KUREBAYASHI, Kyoto (JP); Naoto FUJITA, Kyoto (JP)

(21) Appl. No.: 19/269,492

(22) Filed: Jul. 15, 2025

(30) Foreign Application Priority Data
Aug. 27, 2024 (JP) 2024-145857

(51) Int. Cl. H01L 21/67

(52) U.S. Cl. CPC H10P 72/0404

(57) ABSTRACT

A substrate processing system (10) includes a substrate processing apparatus (1) that supplies a processing fluid to substrates, a supplier (200) that guides a processing fluid to the substrate processing apparatus (1), and a heat collector (40) that collects heat from a drain liquid discharged from the substrate processing apparatus (1). The supplier (200) includes a heat controller (20) that controls the temperature of a processing fluid while circulating the processing fluid in the circulation passage (201), a supply passage (21) that guides a processing fluid from the heat controller (20) to the substrate processing apparatus (1), and a replenishment passage (22) that replenishes the heat controller (20) with a processing fluid. The heat collector (40) includes a heat pump (41) that collects heat from a drain liquid and gives heat to a processing fluid flowing in the replenishment passage (22).

### CROSS-REFERENCE TO RELATED APPLICATIONS

This application claims priority benefit of Japanese Patent Application No. JP2024-145857 filed in the Japan Patent Office on Aug. 27, 2024, the entire disclosure of which is incorporated herein by reference.

### TECHNICAL FIELD

The present invention relates to a substrate processing system that performs processing on a substrate by supplying a processing fluid to the substrate.

### BACKGROUND ART

Conventionally, substrate processing apparatuses that perform processing on semiconductor substrates or other types of substrates (hereinafter, simply referred to as “substrates”) supply various types of processing fluids (including pure water) to substrates to perform processing on the substrates. Depending on the type of processing, a processing fluid may be heated to a desired temperature before supplied to substrates. Heating the processing fluid or maintaining the temperature of the processing fluid may be conducted by, for example, a halogen lamp heater or an electric heater, and high amounts of electric power are consumed by such heaters.

Japanese Patent Application Laid-Open No. 2022-178121 (Document 1) discloses a technique for heating a processing fluid to be supplied by a heat pump to a plurality of substrate processing apparatuses and cooling a coolant. Document 1 shows in FIGS. 11 and 12 that a high-temperature drain liquid is supplied from a substrate processing apparatus to a drain cooler, and the supplied drain liquid is cooled in a cooling circulation passage. The cooling circulation passage is connected to a heat pump device so that heat is transferred from the cooling circulation passage to a heating circulation passage and heats up a processing fluid.

Conventionally, a processing fluid has been circulated and maintained at a fixed temperature and supplied to a substrate processing apparatus when necessary. In this case, if a heat pump is installed directly in the circulation passage as in Document 1, the processing fluid is greatly affected by variances of heat supplied from the heat pump, and this is not preferable for a processing fluid that has a low tolerance for temperature changes.

### SUMMARY OF THE INVENTION

It is an object of the present invention to provide a new technique for making effective use of heat by using a heat pump around a substrate processing apparatus.
Aspect 1 of the present invention is a substrate processing system that includes a substrate processing apparatus that supplies a processing fluid to a substrate, a supplier that guides the processing fluid to the substrate processing apparatus, and a heat collector that collects heat from a drain liquid discharged from the substrate processing apparatus. The supplier includes a heat controller that controls a temperature of the processing fluid while circulating the processing fluid in a circulation passage, a supply passage that guides the processing fluid from the heat controller to the substrate processing apparatus, and a replenishment passage in which the heat controller is replenished with a processing fluid. The heat collector includes a heat pump that collects heat from the drain liquid and applies heat to the processing fluid flowing in the replenishment passage.

According to the present invention, it is possible to reduce electric power required to heat the processing fluid.
Aspect 2 of the present invention is the substrate processing system according to Aspect 1, in which the heat collector further includes a heat exchanger, and the heat pump collects heat from the drain liquid indirectly via the heat exchanger.
Aspect 3 of the present invention is the substrate processing system according to Aspect 2, in which the heat collector further includes a medium tank that is provided between the heat pump and the heat exchanger and that temporarily stores a heating medium flowing from the heat exchanger.
Aspect 4 of the present invention is the substrate processing system according to Aspect 1 (or according to any one of Aspects 1 to 3) that further includes a drain tank that is provided in an exhaust passage for passing the drain liquid and that temporarily stores the drain liquid.
Aspect 5 of the present invention is the substrate processing system according to Aspect 1 (or according to any one of Aspects 1 to 4), in which the heat collector further includes a heat exchanger, and the heat pump applies heat indirectly via the heat exchanger to the processing fluid flowing in the replenishment passage.
Aspect 6 of the present invention is the substrate processing system according to Aspect 5, in which the heat controller includes a circulation tank provided in the circulation passage, a processing liquid flowing in the replenishment passage through the heat exchanger is guided to the circulation tank, and the supplier further includes an auxiliary passage that guides the processing fluid stored in the circulation tank to the replenishment passage in a position upstream of the heat exchanger.
Aspect 7 of the present invention is the substrate processing system according to any one of Aspects 1 to 6, in which the processing fluid is pure water.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a plan view showing a layout of a substrate processing system.

FIG. 2 is a diagram showing a processing unit and a supplier.

FIG. 3 is a diagram showing a configuration of a substrate processing apparatus.

FIG. 4 is diagram showing the supplier and a heat collector.

FIG. 5 is a diagram showing the structure of a heat pump in a simplified manner.

FIG. 6 is a diagram showing another example of the heat collector.

### DETAILED DESCRIPTION

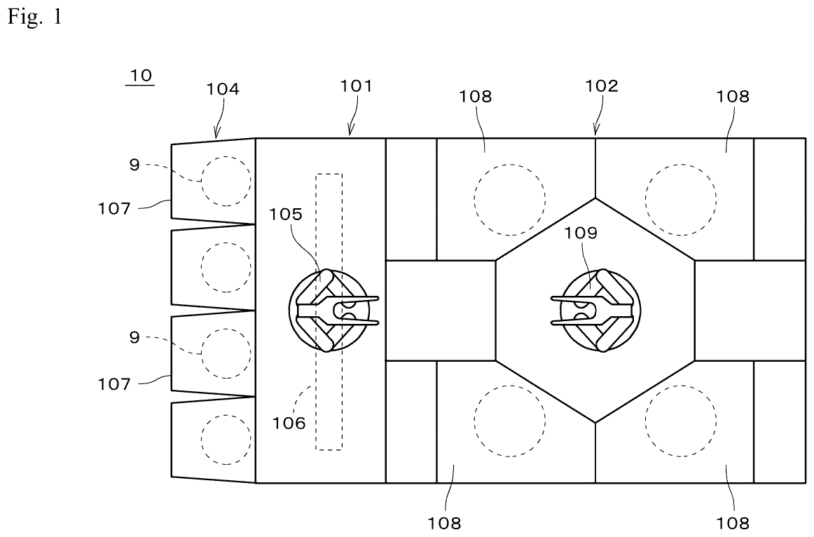

FIG. 1 is a plan view showing a layout of a substrate processing system 10. The substrate processing system 10 is a system that processes semiconductor substrates 9 (hereinafter, simply referred to as “substrates 9”). The substrate processing system 10 includes an indexer block 101 and a processing block 102 joined to the indexer block 101.

The indexer block 101 includes a carrier holder 104, an indexer robot 105, and an IR movement mechanism 106. The carrier holder 104 holds a plurality of carriers 107 each capable of housing a plurality of substrates 9. The carriers 107 (e.g., FOUPs) are held by the carrier holder 104 while being aligned in a predetermined carrier alignment direction. The IR movement mechanism 106 moves the indexer robot 105 in the carrier alignment direction. The indexer robot 105 performs a transport-out operation of transporting substrates 9 out of the carriers 107 and a transport-in operation of transporting substrates 9 into the carriers 107 held by the carrier holder 104. The substrates 9 are carried in a horizontal position by the indexer robot 105.

The processing block 102 includes a plurality of (e.g., four or more) processing units 108 that process substrates 9, and a center robot 109. The processing units 108 are arranged to surround the center robot 109 in plan view. The processing units 108 perform a variety of processing on substrates 9. In the present embodiment, each processing unit 108 has a tower structure in which three sheet-fed substrate processing apparatuses are stacked one above another in an up-down direction.

The center robot 109 performs a transport-in operation of transporting substrates 9 into the substrate processing apparatuses in the processing units 108 and a transport-out operation of transporting substrates 9 out of the substrate processing apparatuses. The center robot 109 further transports substrates 9 among the processing units 108. Substrates 9 are transported in a horizontal position by the center robot 109. The center robot 109 receives substrates 9 from the indexer robot 105 and transfers the substrates 9 to the indexer robot 105.

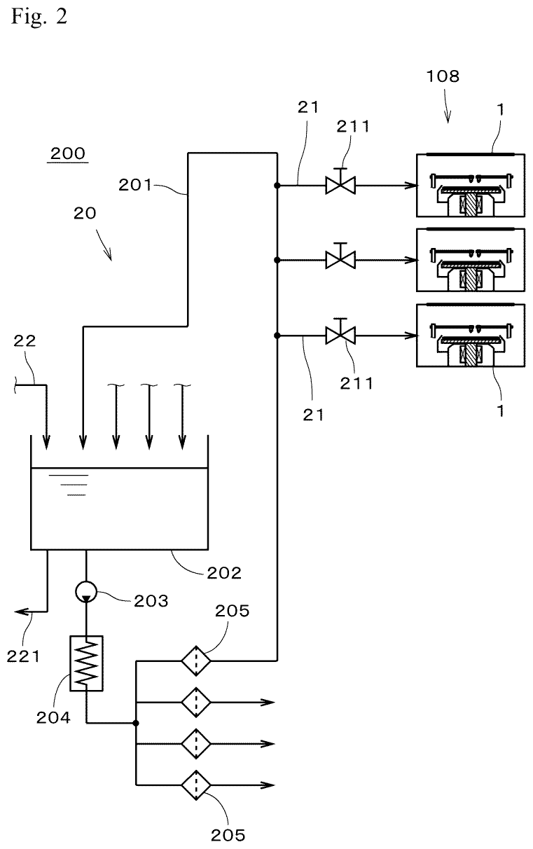

FIG. 2 is a diagram showing one processing unit 108 and a supplier 200 serving as a peripheral constituent element that supplies pure water to the processing unit 108. The supplier 200 includes heat controllers 20, supply passages 21, and a replenishment passage 22. The processing unit 108 has a structure in which three substrate processing apparatuses 1 are stacked one above another in the up-down direction. Each substrate processing apparatus 1 is connected to a supply passage 21 for guiding pure water that is a heated processing fluid (which is de-ionized water and hereinafter expressed as “DIW”). Note that each substrate processing apparatus 1 is also connected to other supply passages for supplying other processing fluids such as a chemical solution, but such a configuration is not shown in FIG. 2. The three supply passages 21 are each provided with a valve 211, and when the valves 211 are open, DIW is supplied to the substrate processing apparatuses 1.

The three supply passages 21 are connected to one circulation passage 201. The circulation passage 201 is provided with a circulation tank 202, a pump 203, a heater 204, and a filter 205. The above-described configuration configures one heat controller 20 that controls the temperature of the DIW while circulating the DIW in the circulation passage 201. Part of the heat controller 20 is shared among other configurations that supply heated DIW to the other processing units 108. That is, the circulation passage 201 branches off into four branch passages on the downstream side of the heater 204, and each branch passage forms part of the circulation passage 201 for supplying the DIW to a different processing unit 108. The branching circulation passage 201 is guided to the circulation tank 202. The circulation tank 202, the pump 203, and the heater 204 are shared among the four heat controllers 20 and provided in a site shared among the four circulation passages 201.

The DIW flows from the circulation tank 202 to the heater 204 by the action of the pump 203 and is heated as necessary to a desired temperature by the heater 204. Various devices may be used as the heater 204, and examples that can be used include a halogen lamp heater and a heating wire. The DIW further flows in the circulation passage 201 via the filter 205 for removing foreign substances and is supplied as necessary from the supply passages 21 to the substrate processing apparatuses 1. The DIW that is not guided to the supply passages 21 further flows in the circulation passage 201 and returns to the circulation tank 202. The temperature of the DIW stored in the circulation tank 202 is measured all the time, and the heater 204 is controlled based on the results of measurement. The heater 204 may be controlled based on the temperatures of the DIW measured on inlet and outlet sides of the heater 204. This allows the plurality of substrate processing apparatus 1 to supply the DIW at a constant temperature all the time. The substrate processing system 10 uses one heater 204 to control the temperature of the DIW in the substrate processing apparatuses 1 in the processing units 108 and thereby achieves the supply of heated DIW with a simple configuration. The heater 204 may have a structure in which a plurality of heater elements are connected in series or in parallel. The DIW is used as a rinsing liquid in the substrate processing apparatuses 1. The DIW may also be used to dilute other processing fluids. The circulation tank 202 in the heat controller 20 is replenished with the DIW flowing from the replenishment passage 22.

The number of substrate processing apparatuses 1 included in each processing unit 108 is not limited to three and may, for example, be four. Preferably, the number of substrate processing apparatuses 1 included in each processing unit 108 may be two or more. Alternatively, the number of substrate processing apparatuses 1 included in each processing unit 108 may be one. Since one heater 204 is provided for the four processing units 108, the cost of manufacturing the substrate processing system 10 can be reduced as compared with the case where a heater is provided in each processing unit 108 or in each substrate processing apparatus 1.

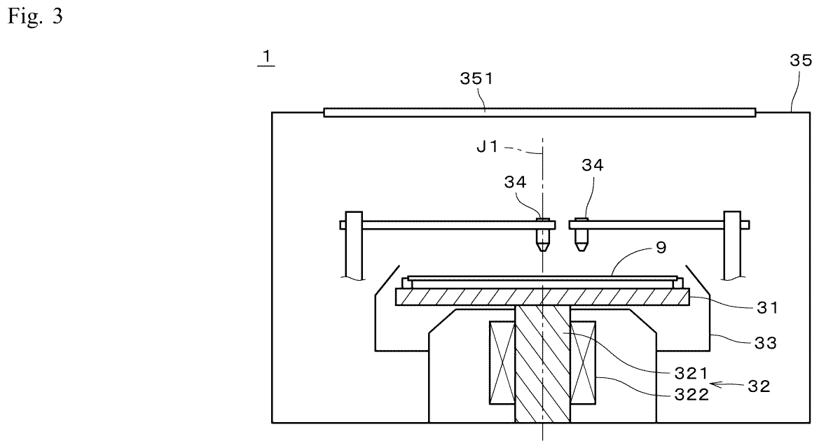

FIG. 3 is a diagram showing a configuration of one substrate processing apparatus 1. The substrate processing apparatus 1 includes a substrate holder 31, a substrate rotation mechanism 32, a cup part 33, a plurality of supply nozzles 34, and a housing 35. The substrate holder 31, the substrate rotation mechanism 32, the cup part 33, and the supply nozzles 34 are placed in the internal space of the housing 35. The canopy of the housing 35 is provided with an airflow former 351 that supplies a gas into the internal space to form a downward-flowing current of air (so-called downflow). For example, a fan filter unit (FFU) may be used as the airflow former 351. The substrate processing apparatus 1 further includes a controller which is not shown, and the controller controls the substrate holder 31, the substrate rotation mechanism 32, the cup part 33, the supply nozzles 34, and other constituent elements.

The substrate holder 31 holds a substrate 9 in a horizontal position. For example, the substrate holder 31 may include a chuck that holds and sandwiches the outer rim of an approximately disk-shaped substrate 9 by a plurality of holding pins. The substrate holder 31 may also be a chuck that comes in contact with and adsorbs the central portion of the lower surface of the substrate 9.

The substrate rotation mechanism 32 is arranged below the substrate holder 31. The substrate rotation mechanism 32 rotates the substrate 9 together with the substrate holder 31 about a rotation axis JI extending in approximately parallel with the up-down direction. The substrate rotation mechanism 32 includes a shaft 321 and a motor 322. The shaft 321 is an approximately column-like or cylinder-like member centering on the rotation axis J1. The shaft 321 extends in the up-down direction and is connected to the central portion of the lower surface of the substrate holder 31. The motor 322 is an electrically rotating motor that rotates the shaft 321. Note that the substrate rotation mechanism 32 may also be any motor having a different structure (e.g., a hollow motor).

The supply nozzles 34 supply a processing fluid to the substrate 9 to perform liquid processing on the substrate 9. Examples of the processing fluid includes DIW serving as a rinsing liquid, and a chemical solution such as a sulfuric acid and hydrogen peroxide mixture (SPM), an ammonia and hydrogen peroxide mixture (SC1), or a hydrochloric acid and hydrogen peroxide mixture (SC2). While FIG. 3 shows two supply nozzles 34 that eject a processing fluid to the upper surface of the substrate 9 from above the substrate 9, other nozzles may also be provided in addition. Each supply nozzle 34 has an exhaust port that is movable by a nozzle movement mechanism which is not shown between a position above the substrate 9 and a position away from above the substrate 9.

The cup part 33 includes a ring-shaped cup centering on the rotation axis J1, and the cup receives a liquid such as a processing fluid that is dispersed to the surroundings from a rotating substrate 9. The bottom of the cup part 33 is provided with a drain port (not shown) through which a processing fluid or the like received by the cup is discharged to the outside of the housing 35.

As one example of the processing performed on a substrate 9 by the substrate processing apparatus 1, firstly, a high-temperature SPM is supplied to a rotating substrate 9 held by the substrate holder 31, and then heated DIW is supplied as a rinsing liquid to the substrate 9. Then, a high-temperature SC1 is supplied to the rotating substrate 9, and thereafter heated DIW is supplied as a rinsing liquid to the substrate 9. When the supply of the rinsing liquid is completed, the substrate 9 is rotated at high speed and dried.

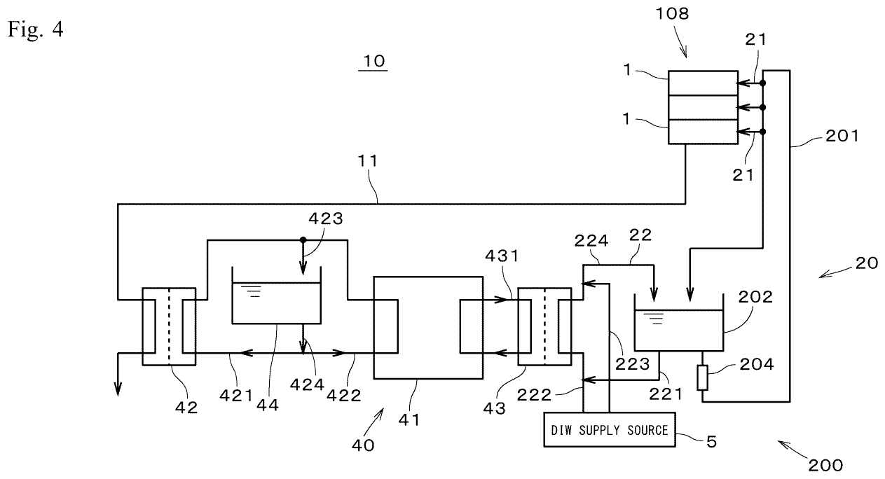

FIG. 4 is a diagram showing a configuration of the substrate processing system 10 in which heat of a drain liquid discharged from the substrate processing apparatuses 1 is used to heat the DIW supplied to the substrate processing apparatuses 1. FIG. 4 shows only one of the processing units 108, and illustration of constituent elements such as pumps and valves is omitted. The controller that controls operations of the constituent elements is also not shown. Only the processing units 108, the supply passages 21, the circulation passage 201, the circulation tank 202, the heater 204, and the replenishment passage 22 are shown as the constituent elements of the supplier 200 in FIG. 2.

A drain liquid that is a high-temperature processing fluid discharged from each substrate processing apparatus 1 is discharged through the exhaust passage 11 to the outside of the substrate processing system 10. The substrate processing system 10 includes a heat collector 40, and the heat controller 40 collects heat of the drain liquid flowing in the exhaust passage 11 and applies the heat to the DIW flowing in the replenishment passage 22. The heat collector 40 is provided as a common configuration for the four processing units 108. That is, the substrate processing system 10 includes the circulation tank 202, the pump 203 (see FIG. 2), the heater 204, and the heat collector 40 as common constituent elements shared among the four processing units 108.

The heat collector 40 includes a heat pump 41, a first heat exchanger 42 arranged on the side of the heat pump 41 that is closer to the exhaust passage 11, a second heat exchanger 43 arranged on the side of the heat pump 41 that is closer to the heat controller 20, and a medium tank 44 arranged between the first heat exchanger 42 and the heat pump 41. The medium tank 44 stores clear water serving as a heating medium. The substrate processing system 10 includes one heat pump 41.

A circulation passage 421 is provided between the first heat exchanger 42 and the medium tank 44. The circulation passage 421 allows passage of clear water from the first heat exchanger 42 to the medium tank 44 and also allows return of the clear water from the medium tank 44 to the first heat exchanger 42. The medium tank 44 functions as a buffer tank that temporarily stores a heating medium flowing from the first heat exchanger 42 in the circulation passage 421. The language “temporarily stores” as used herein refers to discharging an influent fluid out of the tank when necessary while storing the fluid in the tank (the same applies below).

A circulation passage 422 is provided between the medium tank 44 and the heat pump 41. The circulation passage 422 allows passage of clear water from the heat pump 41 to the medium tank 44 and also allows return of the clear water from the medium tank 44 to the heat pump 41. The medium tank 44 also functions as a buffer tank in the circulation passage 422. The circulation passages 421 and 422 share a flow passage 423 that guides clear water into the medium tank 44 and a flow passage 424 that guides clear water to the outside of the medium tank 44, and a pump (not shown) is provided in the flow passage 424.

A circulation passage 431 is provided between the second heat exchanger 43 and the heat pump 41. The circulation passage 431 allows passage of clear water serving as a heating medium from the second heat exchanger 43 to the heat pump 41 and also allows return of the clear water from the heat pump 41 to the second heat exchanger 43.

The substrate processing system 10 is connected to a DIW supply source 5. The DIW supply source 5 is connected to the replenishment passage 22, and DIW supplied from the DIW supply source 5 is guided through the second heat exchanger 43 to the circulation tank 202 along the replenishment passage 22. The supplier 200 includes an auxiliary passage 221 that connects the circulation tank 202 and a portion 222 of the replenishment passage 22 that is located between the DIW supply source 5 and the second heat exchanger 43. The auxiliary passage 221 guides DIW stored in the circulation tank 202 to the replenishment passage 22 at a position forward of the second heat exchanger 43 (i.e., a position on the upstream side). The supplier 200 further includes a bypass passage 223 that connects the DIW supply source 5 and a portion 224 of the replenishment passage 22 that is located between the second heat exchanger 43 and the circulation tank 202. The bypass passage 223 guides DIW to the replenishment passage 22 at a position forward of the circulation tank 202.

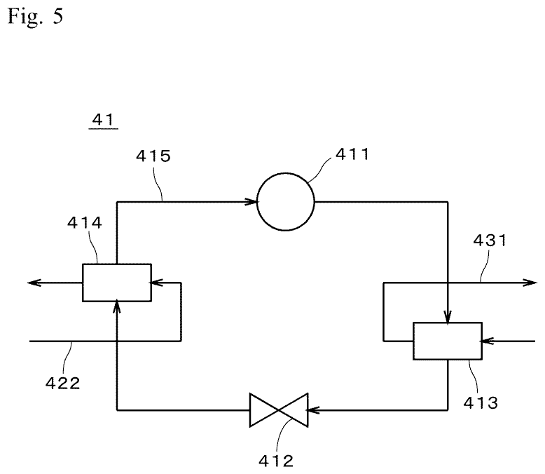

FIG. 5 is a diagram showing the structure of the heat pump 41 in a simplified manner. The heat pump 41 includes a compressor 411, an expansion valve 412, a condenser 413, an evaporator 414, and a circulation passage 415. The compressor 411, the condenser 413, the expansion valve 412, and the evaporator 414 are provided in the circulation passage 415 in the order specified. Carbon dioxide (CO2) is used as a heating medium flowing in the circulation passage 415. Note that the heating medium used in the heat pump 41 is not limited to carbon dioxide. The condenser 413 is connected to the circulation passage 431 (see FIG. 4). The evaporator 414 is connected to the circulation passage 422.

The compressor 411 is a compressor pump. A heating medium of a gas that is compressed by the compressor 411 to have a raised temperature applies heat to clear water flowing in the circulation passage 431 at the condenser 413 serving as a heat exchanger and becomes a liquid. The heating medium is guided from the condenser 413 to the expansion valve 412, and after suffering a temperature drop caused by a reduction in pressure, receives heat from clear water flowing in the circulation passage 422 at the evaporator 414 serving as a heat exchanger and becomes a gas by evaporation. Then, the heating medium returns to the compressor 411. Through the above-described operations, the heat pump 41 heats the clear water flowing in the circulation passage 431 by using the heat of the clear water flowing in the circulation passage 422. Since the heat pump 41 mainly consumes electric power during compression of the heating medium, in principle the heat pump 41 exerts thermal capability that exceeds power consumption.

Next description is given regarding operations of the heat collector 40 shown in FIG. 4. Drain liquids discharged from the substrate processing apparatuses 1 are guided to the first heat exchanger 42 through the exhaust passage 11. The exhaust passage 11 is provided for each type of drain liquid, and only one exhaust passage 11 is shown in FIG. 4. The heat collector 40 shown in FIG. 4 does not necessarily have to be provided in all of the exhaust passages 11. The temperature of the drain liquid may preferably be higher than or equal to 20° C. and lower than or equal to 65° C. Examples of the drain liquid include used SPM, used SC1, used SC2, and heated DIW (Hot-DIW).

The first heat exchanger 42 applies the heat of the drain liquid to the clear water flowing in the circulation passage 421. The drain liquid flows intermittently in the exhaust passage 11, but the presence of the medium tank 44 in the circulation passage 421 alleviates a change in the temperature of the clear water. The clear water is guided to the evaporator 414 of the heat pump 41 in the circulation passage 422. Accordingly, the heat of the clear water on the side of the evaporator 414 is used to heat the clear water on the side of the condenser 413. That is, the heat of the clear water on the side of the first heat exchanger 42 is used to heat the clear water flowing on the side of the second heat exchanger 43 in the circulation passage 431.

The heated clear water is guided to the second heat exchanger 43 through the circulation passage 431, and the second heat exchanger 43 applies heat to DIW flowing in the replenishment passage 22. That is, the heat pump 41 applies heat indirectly via the second heat exchanger 43 to the DIW which is the processing fluid flowing in the replenishment passage 22. The heated DIW is guided to the circulation tank 202.

Since the DIW flowing in the replenishment passage 22 is heated by the heat pump 41, it is possible to reduce electric power required to heat the DIW flowing in the circulation passage 201, i.e., electric power consumed by the heater 204. As a result, a low-priced heater may be used as the heater 204, and extra loads required to cool the drain liquid can be reduced. Moreover, since the DIW flowing in the replenishment passage 22 is heated by the heat pump 41, it is possible to suppress a change in the temperature of the DIW flowing in the circulation passage 201 as compared with the case where the DIW flowing in the circulation passage 201 is heated by a heat pump.

In the heat collector 40, the heat pump 41 collects heat from the drain liquid indirectly via the first heat exchanger 42. This prevents corrosion of the heat pump 41 caused by the drain liquid. In the heat collector 40, the heat pump 41 also applies heat to the DIW flowing in the replenishment passage 22 indirectly via the second heat exchanger 43. This enables easily maintaining cleanliness of the DIW which is so-called ultrapure water, while ensuring the resistance of the heat pump 41 to pressure. The term “indirectly” as used herein refers to non-connection of the heat pump 41 to the exhaust passage 11 and the replenishment passage 22, and heat may be exchanged in various forms between the heat pump 41 and the exhaust passage 11 or the replenishment passage 22.

As described previously, the DIW supplied from the DIW supply source 5 can be supplied via the bypass passage 223 to the portion 224 of the replenishment passage 22 that is located between the second heat exchanger 43 and the circulation tank 202. The heat pump 41 is preferably operated continuously as long as possible. If the temperature of the DIW derived from the second heat exchanger 43 becomes too high due to the continuous operation of the heat pump 41, the valve in the bypass passage 223 may be opened to lower the temperature of the DIW before the DIW is supplied to the circulation tank 202.

The auxiliary passage 221 that guides the DIW from the circulation tank 202 to the portion 222 of the replenishment passage 22 that is located between the second heat exchanger 43 and the DIW supply source 5 is used to guide the DIW heated via the auxiliary passage 221 to the second heat exchanger 43 and to make the inside of the second heat exchanger 43 in a steady state at the time of, for example, activation of the heat collector 40. The auxiliary passage 221 may branch off at a position between the pump 203 and the heater 204 in FIG. 2.

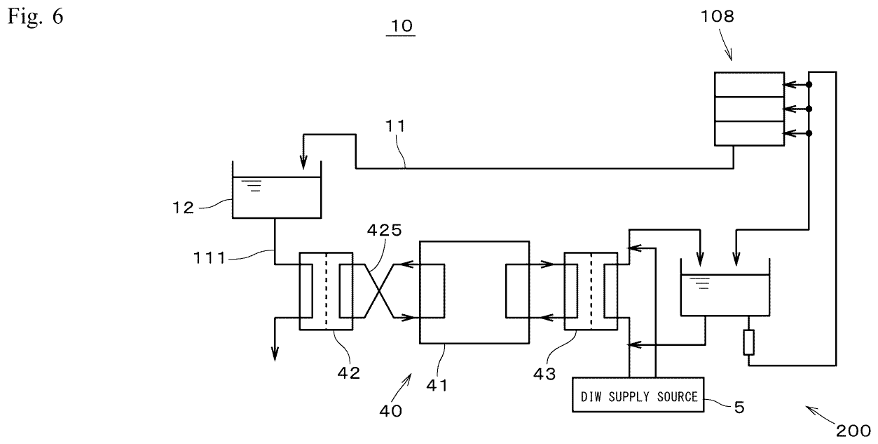

FIG. 6 is a diagram showing another example of the heat collector 40. In the example shown in FIG. 6, the medium tank 44 is omitted from the heat collector 40 shown in FIG. 4, and a drain tank 12 is provided in the exhaust passage 11. In FIG. 6, constituent elements that are identical to those in FIG. 4 are given the same reference signs.

The heat collector 40 shown in FIG. 6 is provided with one circulation passage 425 between the first heat exchanger 42 and the heat pump 41. Clear water flowing in the circulation passage 425 receives heat of a drain liquid flowing in the exhaust passage 11 at the first heat exchanger 42 and guides the heat to the heat pump 41.

As described previously, the drain liquid is discharged intermittently from the substrate processing apparatuses 1. The heat collector 40 includes the drain tank 12 provided in the exhaust passage 11, and the drain liquid is temporarily stored in the drain tank 12. Then, the drain liquid flows at a constant flow rate in a portion 111 of the exhaust passage 11 that is located downstream of the drain tank 12. This allows the drain liquid to flow through the first heat exchanger 42 at a constant flow rate and makes it possible to apply a constant amount of heat per unit time to the clear water flowing on the side of the heat pump 41. As a result, the heat pump 41 can be operated in a constant state or at fixed intervals. This realizes stable operation of the heat collector 40.

The substrate processing system 10 described above is merely one example, and various forms are adoptable as the substrate processing system 10. For example, the number of processing units 108 included in the substrate processing system 10 may be one, or may be two or more. The number of substrate processing apparatuses 1 included in the substrate processing system 10 may also be one.

Various structures are adoptable as the structures of the first heat exchanger 42 and the second heat exchanger 43. Since the first heat exchanger 42 and the second heat exchanger 43 are directly or indirectly connected to the heat pump 41, it is preferable that the flow rates of fluids flowing in two internal passages for heat exchange are adjustable. However, the structures of these heat exchangers are not limited to the examples described above, and may be a simpler structure in which a pipe for passing one fluid is arranged simply inside a tank that temporarily stores the other fluid. The heat exchangers may adopt various forms as long as they can exchange heat between fluids flowing in two flow passages.

The processing fluid supplied to the substrates 9 in the substrate processing apparatus 1, i.e., the processing fluid whose temperature is controlled by the heat controller 20 during circulation in the circulation passage 201, is not limited to DIW. For example, the temperature of a chemical solution such as a sulfuric acid, ammonia water, a hydrogen peroxide solution, or a hydrofluoric acid may be controlled during circulation in the circulation passage 201. Such chemical solutions (practically, processing fluids) are mixed together and ejected as a processing fluid such as SPM, SC1, or SC2 to substrates. In this case, the DIW described above may be translated as a processing fluid including chemical solutions, and the replenishment passage 22 replenishes the heat controller 20 with this processing fluid. As described previously, the drain liquid discharged from the substrate processing apparatuses 1 and targeted for heat collection by the heat collector 40 may be any of various fluids. Thus, the processing fluid and the drain liquid may be different types of liquids, or may be the same type of liquids.

In the case where the processing fluid is a chemical solution such as SPM, SC1, or SC2, the presence of the second heat exchanger 43 between the heat pump 41 and the replenishment passage 22 eliminates the need for the heat pump 41 to have an anti-corrosive structure.

Depending on the type of the drain liquid, the first heat exchanger 42 may be omitted. In this case, the exhaust passage 11 is guided to the heat pump 41, and the heat of the drain liquid is directly applied to the heat pump 41. Similarly, depending on the type of the processing fluid supplied to the substrate processing apparatuses 1, the second heat exchanger 43 may be omitted. In this case, the processing fluid flowing in the replenishment passage 22 is directly heated by the heat pump 41. In this way, in the heat controller 40, the peripheral configuration of the heat pump 41 that collects heat from the drain liquid and applies the heat to the processing fluid flowing in the replenishment passage 22 may be modified in various ways. In any configuration, it is possible, by heating the processing fluid flowing in the replenishment passage 22 by the heat pump 41 using the heat of the drain liquid, to reduce electric power required to heat the processing fluid while suppressing a change in the temperature of the processing fluid flowing in the circulation passage 201.

In the example shown in FIG. 4, the substrate processing system 10 includes the medium tank 44, whereas in the example shown in FIG. 6, the substrate processing system 10 includes the drain tank 12. Alternatively, the substrate processing system 10 may omit both of the tanks, or may include both of the tanks. Although constituent elements such as pumps, valves, and filters are not shown in FIGS. 4 and 6, these constituent elements may be provided as appropriate when necessary.

The substrates 9 to be processed by the substrate processing apparatuses 1 are not limited to semiconductor wafers, and may be other substrates such as glass substrates for photomask, glass substrates for liquid crystal display, glass substrates for plasma display, field emission display (FED) substrates, optical disk substrates, magnetic disk substrates, or magneto-optical disk substrates. The layout of the substrate processing system 10 shown in FIG. 1 is merely one example, and it may not include a robot or the like, or may include only one substrate holder or one substrate rotation mechanism.

The configurations of said above-described preferred embodiment and variations may be appropriately combined as long as there are no mutual inconsistencies.

While the invention has been shown and described in detail, the foregoing description is in all aspects illustrative and not restrictive. It is therefore understood that numerous modifications and variations can be devised without departing from the scope of the invention.

### REFERENCE SIGNS LIST

1 substrate processing apparatus
9 substrate
10 substrate processing system
11 exhaust passage
12 drain tank
20 heat controller
21 supply passage
22 replenishment passage
40 heat collector
41 heat pump
42 first heat exchanger
43 second heat exchanger
44 medium tank
200 supplier
201 circulation passage
202 circulation tank
221 auxiliary passage

1. A substrate processing system comprising:
a substrate processing apparatus that supplies a processing fluid to a substrate;
a supplier that guides said processing fluid to said substrate processing apparatus; and
a heat collector that collects heat from a drain liquid discharged from said substrate processing apparatus,
wherein said supplier includes:
a heat controller that controls a temperature of said processing fluid while circulating said processing fluid in a circulation passage;
a supply passage that guides said processing fluid from said heat controller to said substrate processing apparatus; and
a replenishment passage in which said heat controller is replenished with a processing fluid, and
said heat collector includes a heat pump that collects heat from said drain liquid and applies heat to said processing fluid flowing in said replenishment passage.

2. The substrate processing system according to claim 1, wherein
said heat collector further includes a heat exchanger, and
said heat pump collects heat from said drain liquid indirectly via said heat exchanger.

3. The substrate processing system according to claim 2, wherein
said heat collector further includes a medium tank that is provided between said heat pump and said heat exchanger and that temporarily stores a heating medium flowing from said heat exchanger.

4. The substrate processing system according to claim 1, further comprising:
a drain tank that is provided in an exhaust passage for passing said drain liquid and that temporarily stores said drain liquid.

5. The substrate processing system according to claim 1, wherein
said heat collector further includes a heat exchanger, and
said heat pump applies heat indirectly via said heat exchanger to said processing fluid flowing in said replenishment passage.

6. The substrate processing system according to claim 5, wherein
said heat controller includes a circulation tank provided in said circulation passage,
a processing liquid flowing in said replenishment passage through said heat exchanger is guided to said circulation tank, and
said supplier further includes an auxiliary passage that guides said processing fluid stored in said circulation tank to said replenishment passage in a position upstream of said heat exchanger.

7. The substrate processing system according to claim 1, wherein
said processing fluid is pure water.
